(19) United States
(12) Patent Application Publication
(10) Pub. No.: US 2012/0178223 A1
(43) Pub. Date: Jul. 12, 2012

(54) Method of Manufacturing High Breakdown Voltage Semiconductor Device

(75) Inventors: Yoshinosuke Nishijo, Hyogo-ken (JP); Hironobu Shibata, Hyogo-ken (JP); Hiroshi Ishibashi, Hyogo-ken (JP)

(73) Assignee: Kabushiki Kaisha Toshiba, Tokyo (JP)

(21) Appl. No.: 13/235,193

(22) Filed: Sep. 16, 2011

(30) Foreign Application Priority Data
Jan. 7, 2011 (JP) 2011-001696

(51) Int. Cl. H01L 21/331

(52) U.S. Cl. 438/138; 257/E21.383

(57) ABSTRACT

According to one embodiment, a method of manufacturing a semiconductor device includes a polishing step, a first amorphous silicon film formation step, a single crystallization step and a buffer layer formation step. In the first amorphous silicon film formation step, a first amorphous silicon film of the first conductivity type is formed on the polished back surface of the high-resistance layer, the first amorphous silicon film having a higher impurity concentration than the high-resistance layer. In the single crystallization step, the first amorphous silicon film is single-crystallized by irradiating the first amorphous silicon film with a first laser. In the buffer layer formation step, the formation and single-crystallization of the first amorphous silicon film are repeated more than once to form a buffer layer of the first conductivity type on the back surface of the high-resistance layer, the buffer layer having a higher impurity concentration than the high-resistance layer.

### CROSS REFERENCE TO RELATED APPLICATION

This application is based upon and claims the benefit of priority from the prior Japanese Patent Application No. 2011-001696, filed on Jan. 7, 2011, the entire contents of which are incorporated herein by reference.

### FIELD

Embodiments described herein relate to a method of manufacturing a high breakdown voltage semiconductor device.

### BACKGROUND

In an IGBT (insulated gate bipolar transistor) that is a power device, a base layer, an emitter layer and a gate are formed on a front side of a high-resistance layer, and thereafter the back surface side of the high-resistance layer is polished to adjust the wafer thickness to obtain a predetermined breakdown voltage. After the backside polishing, a high-concentration buffer layer and a high-concentration collector layer are formed on the back surface side of the high-resistance layer. The high-concentration buffer layer and the high-concentration collector layer are formed using backside ion implantation with high-temperature heat treatment or laser irradiation, for example.

When the high-concentration buffer layer and the high-concentration collector layer are formed using backside ion implantation with high-temperature heat treatment or laser irradiation, a high acceleration ion implantation apparatus is required, which leads to problems such as an impurity profile broad in a depth direction and occurrence of many defects. Meanwhile, when relatively low temperature epitaxy is used to form a high-concentration buffer layer or high-concentration collector layer having a steep impurity profile, there is a problem that the surface is roughened by crystal defects or void defects.

### BRIEF DESCRIPTION OF THE DRAWINGS

FIG. 1 is a cross-sectional view showing an IGBT according to a first embodiment;

FIGS. 2a and 2b are graphs each showing an impurity profile of an N⁺ buffer layer and a P⁺ collector layer according to the first embodiment, FIG. 2a showing the impurity profile along the line A-A in the IGBT shown in FIG. 1, and FIG. 2b showing the impurity profile of a comparative example;

FIG. 3 is a cross-sectional view showing a step of manufacturing an IGBT according to the first embodiment;

FIG. 4 is a cross-sectional view showing a step of manufacturing an IGBT according to the first embodiment;

FIG. 5 is a cross-sectional view showing a step of manufacturing an IGBT according to the first embodiment;

FIG. 6 is a graph showing absorption coefficients of single crystal silicon, polycrystalline silicon and amorphous silicon according to the first embodiment;

FIG. 7 is a cross-sectional view showing a step of manufacturing an IGBT according to the first embodiment;

FIG. 8 is a cross-sectional view showing a step of manufacturing an IGBT according to the first embodiment;

FIG. 9 is a cross-sectional view showing a step of manufacturing an IGBT according to the first embodiment;

FIG. 10 is a view showing a method of manufacturing an IGBT of a modification;

FIG. 11 is a view showing the method of manufacturing an IGBT of the modification;

FIG. 12 is a cross-sectional view showing a RC-IGBT according to a second embodiment;

FIG. 13 is a cross-sectional view showing a step of manufacturing a RC-IGBT according to the second embodiment;

FIG. 14 is a cross-sectional view showing a step of manufacturing a RC-IGBT according to the second embodiment;

FIG. 15 is a cross-sectional view showing a step of manufacturing a RC-IGBT according to the second embodiment;

FIG. 16 is a cross-sectional view showing a step of manufacturing a RC-IGBT according to the second embodiment;.

FIG. 17 is a cross-sectional view showing a step of manufacturing a RC-IGBT according to the second embodiment; and

FIG. 18 is a cross-sectional view showing a step of manufacturing a RC-IGBT according to the second embodiment.

### DETAILED DESCRIPTION

A method of manufacturing a semiconductor device according to an embodiment is a method of manufacturing a semiconductor device including a base layer of a second conductivity type provided in a front surface region of a high-resistance layer of a first conductivity type, an emitter layer of the first conductivity type having a higher impurity concentration than the high-resistance layer provided in a front surface region of the base layer, and a gate electrode film insulated from the base layer and the emitter layer by a gate insulating film, the method including a polishing step, a first amorphous silicon film formation step, a single crystallization step and a buffer layer formation step. In the polishing step, a back surface of the high-resistance layer is polished. In the first amorphous silicon film formation step, a first amorphous silicon film of the first conductivity type is formed on the polished back surface of the high-resistance layer, the first amorphous silicon film having a higher impurity concentration than the high-resistance layer. In the single crystallization step, the first amorphous silicon film is single-crystallized by irradiating the first amorphous silicon film with a first laser. In the buffer layer formation step, the formation and single-crystallization of the first amorphous silicon film are repeated more than once to form a buffer layer of the first conductivity type on the back surface of the high-resistance layer, the buffer layer having a higher impurity concentration than the high-resistance layer.

Further embodiments are described below with reference to the drawings. In the drawings, the same or similar portions are denoted by the same or similar reference numerals.

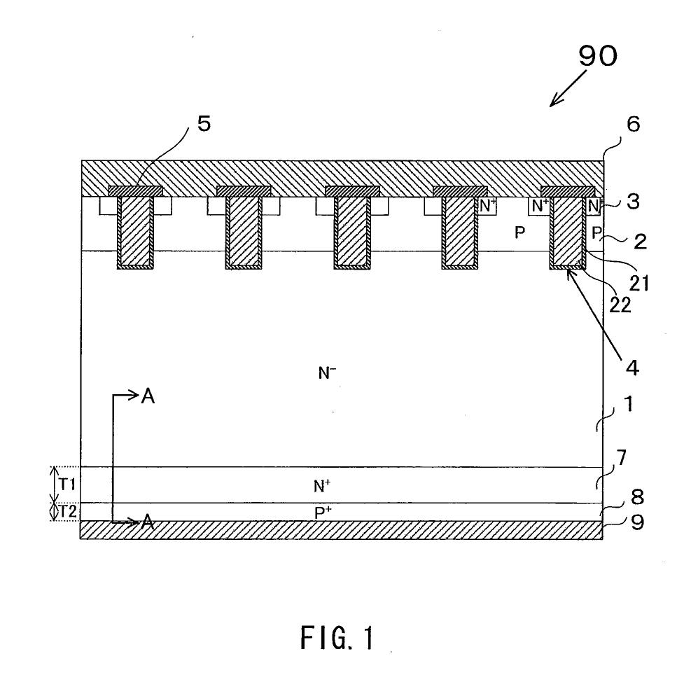

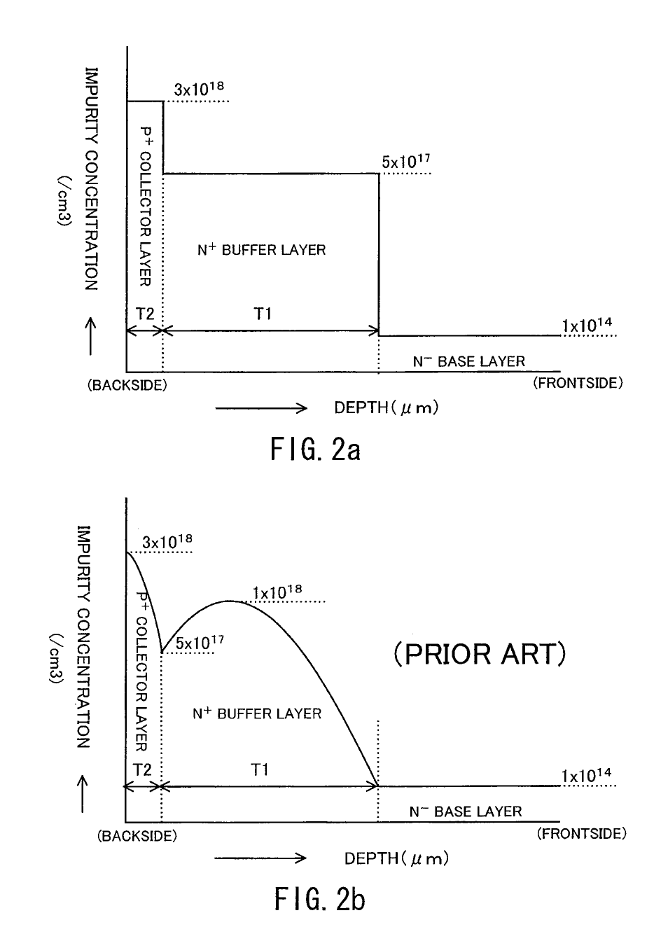

A method of manufacturing a semiconductor device according to a first embodiment is described with reference to the drawings. FIG. 1 is a cross-sectional view showing an IGBT as the semiconductor device. FIGS. 2a and 2b are graphs each showing an impurity profile of an N⁺ buffer layer and a P⁺ collector layer in the IGBT. FIG. 2a shows the impurity profile along the line A-A in FIG. 1. FIG. 2b shows the impurity profile of a comparative example. In the embodiment, a heavily-doped amorphous silicon film is crystallized by laser irradiation to form the N⁺ buffer layer and the P⁺ collector layer.

As shown in FIG. 1, the IGBT (insulated gate bipolar transistor) 90 as the semiconductor device is a punch-through type trench IGBT. The IGBT 90 is used in various fields as consumer power elements as well as industrial power elements.

In the IGBT 90, a P base layer 2 is provided in a first main surface (front surface) region of an N⁻ base layer 1 that is a high-resistance layer. In a first main surface (front surface) region of the P base layer 2, an N⁺ emitter layer 3 is provided, which has a higher impurity concentration than the N⁻ base layer 1. A trench 4 is provided, which penetrates the N⁺ emitter layer 3 and the P base layer 2, and reaches the front surface of the N⁻ base layer 1. In the trench 4, a gate insulating film 21 and a gate electrode film 22 are buried so as to cover the trench 4. The gate insulating film 21 and the gate electrode film 22 function as a trench gate.

An insulating film 5 is provided on the P base layer 2, the N⁺ emitter layer 3, the gate insulating film 21 and the gate electrode film 22. The insulating film 5 on the P base layer 2 and the N⁺ emitter layer 3 is etched to form an opening which exposes the P base layer 2 and the N⁺ emitter layer 3. This opening is formed away from the trench gate. An emitter electrode 6 is provided on the insulating film 5 and the exposed P base layer 2 and N⁺ emitter layer 3.

On a second main surface (back surface) of the N⁻ base layer 1 that is the high-resistance layer, the second main surface being opposite to the first main surface, an N⁺ buffer layer 7 is provided, which has a layer thickness T1 and a higher impurity concentration than the N⁻ base layer 1. On a second main surface (back surface) of the N⁺ buffer layer 7, the second main surface being opposite to a first main surface in contact with the N⁻ base layer 1, a P⁺ collector layer 8 is provided, which has a layer thickness T2 and a higher impurity concentration than the P base layer 2. On a second main surface (back surface) of the P⁺ collector layer 8, the second main surface being opposite to a first main surface in contact with the N⁺ buffer layer 7, a collector electrode 9 is provided. Although the names “collector” and “emitter” are used for the IGBT in the embodiment, the collector is also referred to as a drain or anode, and the emitter is also referred to as a source or cathode.

As shown in FIG. 2a, in the punch-through type trench IGBT 90 of the embodiment, the P⁺ collector layer 8 is set to have a constant impurity concentration of 3×10¹⁸/cm³, for example, and to have the layer thickness T2. Meanwhile, the N⁺ buffer layer 7 is set to have a constant impurity concentration of 5×10¹⁷/cm³, for example, and to have the layer thickness T1. In other words, a connection portion between the P⁺ collector layer 8 and the N⁺ buffer layer 7 has a steep impurity profile. The N⁻ base layer 1 is set to have an impurity concentration of, for example, 1×10¹⁴/cm³ and is in contact with the N⁺ buffer layer 7 having the impurity concentration of 5×10¹⁷/cm³.

In the embodiment, the N⁺ buffer layer 7 and the P⁺ collector layer 8 are formed by irradiating an amorphous silicon film having a high impurity concentration with a laser to cause the amorphous silicon film to undergo single crystallization (solid-phase epitaxy or liquid-phase epitaxy) (details are described later). The laser irradiation raises the temperature of the amorphous silicon film, but the single crystal silicon layer such as the N⁻ base layer 1 is less likely to be affected by the laser irradiation and is thus unlikely to have the temperature increased by the laser irradiation. Accordingly, defects are reduced, and the N⁺ buffer layer 7 and P⁺ collector layer 8 having a steep impurity profile can be provided.

On the other hand, as shown in FIG. 2b, in the punch-through type trench IGBT of the comparative example, a P⁺ collector layer 8 is set to have a layer thickness T2 and to have an impurity concentration which is higher (3×10¹⁸/cm³) on the collector electrode 9 side and is lower (5×10¹⁷/cm³) toward the N⁺ buffer layer 7, for example. The N⁺ buffer layer 7 is set to have a layer thickness T1 and to have a broad impurity concentration distribution, in which the impurity concentration is low (5×10¹⁷/cm³) in the connection portion with the P⁺ collector layer 8, is high (1×10¹⁸/cm³) in the middle, and is lower toward the N⁻ base layer 1, for example. The N⁺ buffer layer 7 is formed using, for example, a high acceleration ion implantation apparatus and laser irradiation. Thus, it is difficult for the connection portion between the P⁺ collector layer 8 and the N⁺ buffer layer 7 to have a steep impurity profile. Moreover, heat treatment of a high dose ion-implanted layer makes it difficult to reduce the defects.

Here, the thicknesses of the N⁻ base layer 1, N⁺ buffer layer 7 and P⁺ collector layer 8 are set in accordance with the characteristics required for the IGBT. The thickness of the N⁻ base layer 1 is set to 10 μm per 100 V, for example. The thickness of the N⁺ buffer layer 7 is set in a range of 3 to 15 μm, for example. The thickness of the P⁺ collector layer 8 is set in a range of 0.3 to 3 μm, for example. In the case of a non-punch type IGBT, the P⁺ collector layer 8 is required to have a thickness of 10 μm, for example. On the other hand, in the punch-through type trench IGBT 90, the thickness of the P⁺ collector layer 8 is not considered to be as important as those of the N⁻ base layer 1 and the N⁺ buffer layer 7. Here, the punch-through type trench IGBT 90 is for 1000 V, and the thickness of the N⁻ base layer 1 is set to 100 μm, the layer thickness T1 of the N⁺ buffer layer 7 is set to 6 μm, and the layer thickness T2 of the P⁺ collector layer 8 is set to 1 μm.

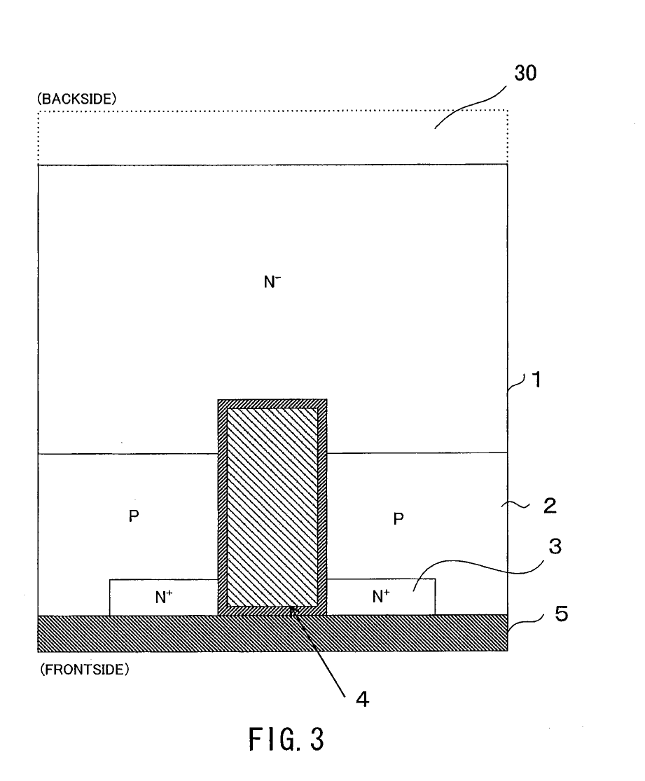

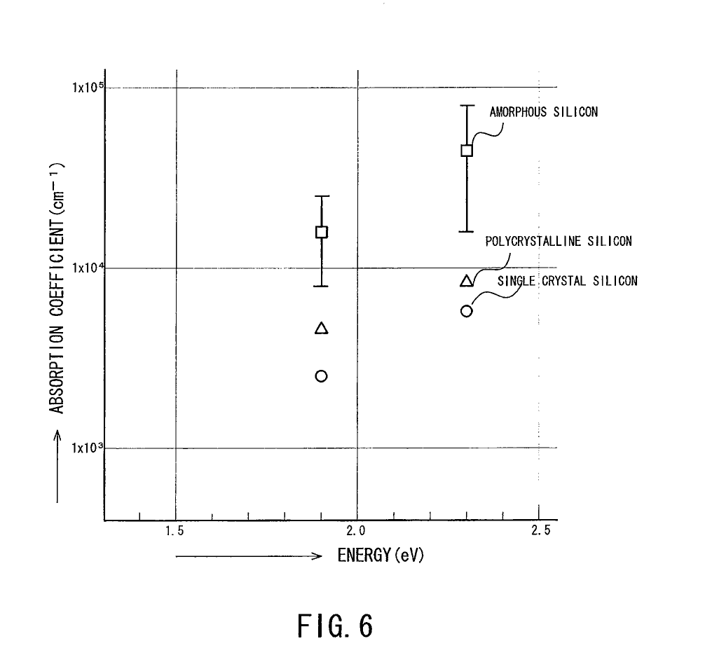

Next, a method of manufacturing an IGBT is described with reference to FIGS. 3 to 9. FIGS. 3 to 5 and FIGS. 7 to 9 are cross-sectional views showing the steps of manufacturing an IGBT. FIG. 6 is a graph showing absorption coefficients of single crystal silicon, polycrystalline silicon and amorphous silicon. Note that, in each of FIGS. 3 to 5 and FIGS. 7 to 9, the upside of the drawing corresponds to the back surface side.

As shown in FIG. 3, after an N⁻ base layer 1, a P base layer 2, an N⁺ emitter layer 3, a trench gate and an insulating film 5 are formed, a second main surface (back surface) of the N⁻ base layer 1 is backside-polished for a predetermined thickness (backside polishing region 30) so as to obtain the characteristics required for a punch-through type planar IGBT 90. After the backside polishing, the polished surface is cleaned by post-polishing treatment.

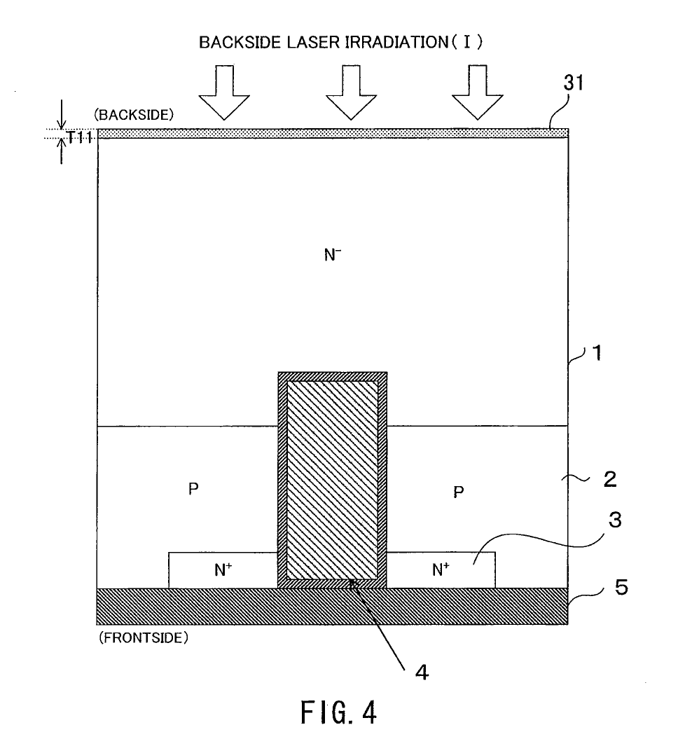

Next, as shown in FIG. 4, an N⁺ amorphous silicon film 31 which is heavily doped with As (arsenic) and has a film thickness T11 is deposited on the polished second main surface (back surface) of the N⁻ base layer 1 by use of a CVD (chemical vapor deposition) method, for example. For example, the CVD growth temperature is set in a range of 200 to 400° C., and the film thickness T11 is set to 0.5 μm. Here, it is preferable to select the conditions that allow the grain size of the N⁺ amorphous silicon film 31 to be reduced.

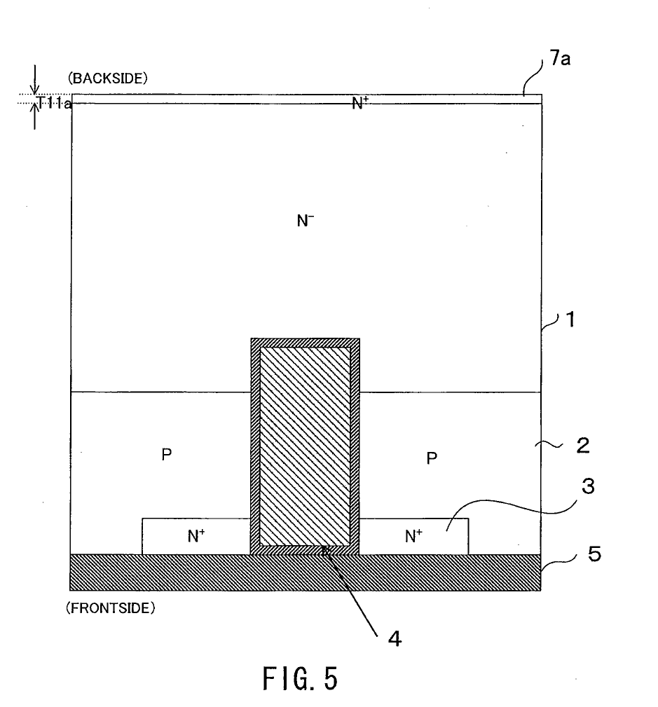

After the formation of the N⁺ amorphous silicon film 31, the N⁺ amorphous silicon film 31 is irradiated with a laser to be single-crystallized (e.g., melted to be crystallized). As shown in FIG. 5, the N⁺ amorphous silicon film 31 is single-crystallized to become a first N⁺ buffer layer 7a having a layer thickness T11a.

Here, the laser irradiation conditions are determined based on absorption coefficient characteristics for the single crystal silicon, polycrystalline silicon and amorphous silicon shown in FIG. 6.

As shown in FIG. 6, the absorption coefficient of the polycrystalline silicon is not increased relative to the absorption coefficient of the single crystal silicon. To be more specific, the absorption coefficient of the polycrystalline silicon is increased 1.5 times when the laser light energy is 1.9 eV, and is increased 1.2 times when the laser light energy is 2.3 eV. On the other hand, the absorption coefficient of the amorphous silicon is increased as the grain size is reduced, and is more than 10 times larger than that of the single crystal silicon. To be more specific, the absorption coefficient of the amorphous silicon is increased 20 times at the maximum when the laser light energy is 1.9 eV, and is increased 14 times at the maximum when the laser light energy is 2.3 eV.

In other words, when irradiated with a predetermined laser, the amorphous silicon absorbs much more laser light than the single crystal silicon, and is increased in temperature to be single-crystallized. On the other hand, the single crystal silicon is less likely to absorb the laser light, and thus the temperature of the single crystal silicon is unlikely to be increased. For this reason, the layer such as the N⁻ base layer 1 made of single crystal silicon is not melted, and thus the amorphous silicon can be selectively single-crystallized. With the polycrystalline silicon, on the other hand, the selective single crystallization is difficult.

For the laser, a pulse laser of μ second or less having a wavelength (λ) of 532 nm (second harmonic of a YAG laser) and energy of 0.5 to 5 J/cm² is used. For example, a pulse laser having a pulse width of 100 ns is used.

While, here, the second harmonic of the YAG laser is used, the third harmonic of the YAG laser (λ=355 nm), a YLF laser, a YVO4 laser or the like may be appropriately used. Note that when a laser having a wavelength shorter than 532 nm is used, the laser light is unlikely to reach the N⁺ amorphous silicon film 31 on the N⁻ base layer 1 interface side. For this reason, it is preferable that the film thickness T11 of the N⁺ amorphous silicon film 31 is reduced.

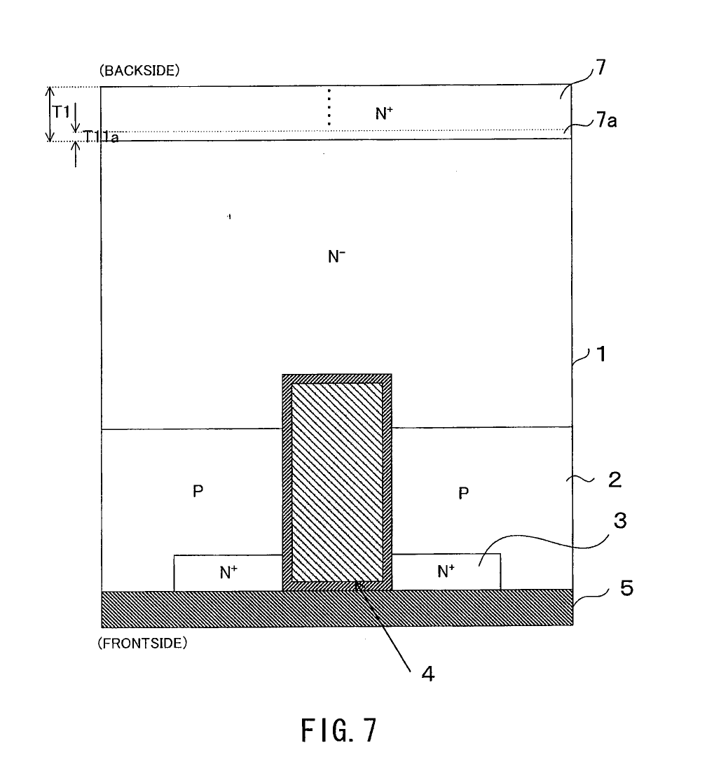

Subsequently, as shown in FIG. 7, the step of irradiating with a laser the N⁺ amorphous silicon film 31 which is heavily doped with As (arsenic) and has the film thickness T11, and of single-crystallizing the N⁺ amorphous silicon film 31 is repeated more than once to form an N⁺ buffer layer 7 having a layer thickness T1.

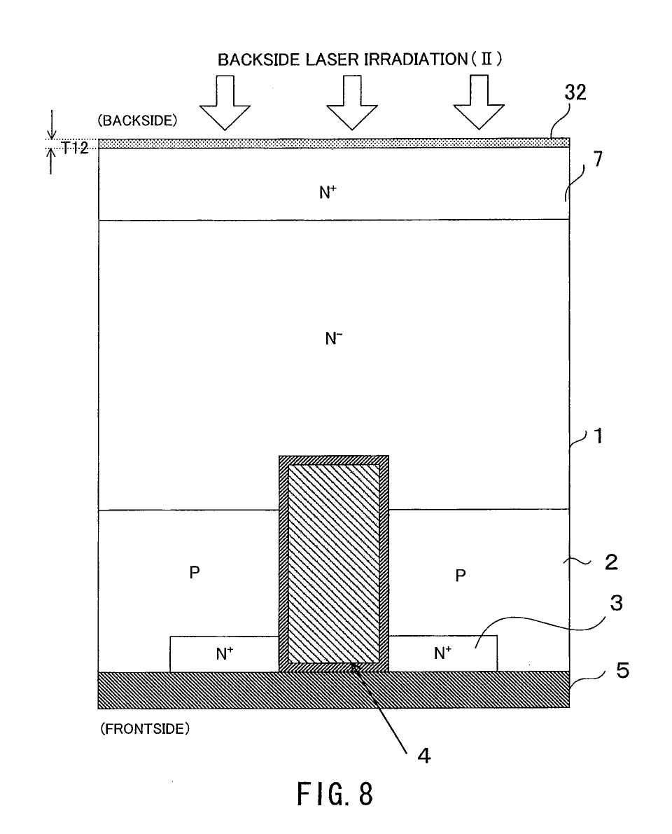

Then, as shown in FIG. 8, a P⁺ amorphous silicon film 32 which is heavily doped with B (boron) and has a film thickness T12 is deposited on a second main surface (back surface) of the N⁺ buffer layer 7 by use of the CVD method, for example. For example, the CVD growth temperature is set in a range of 200 to 400° C., and the film thickness T12 is set to 0.5 μm. Here, it is preferable to select the conditions that allow the grain size of the P⁺ amorphous silicon film 32 to be reduced.

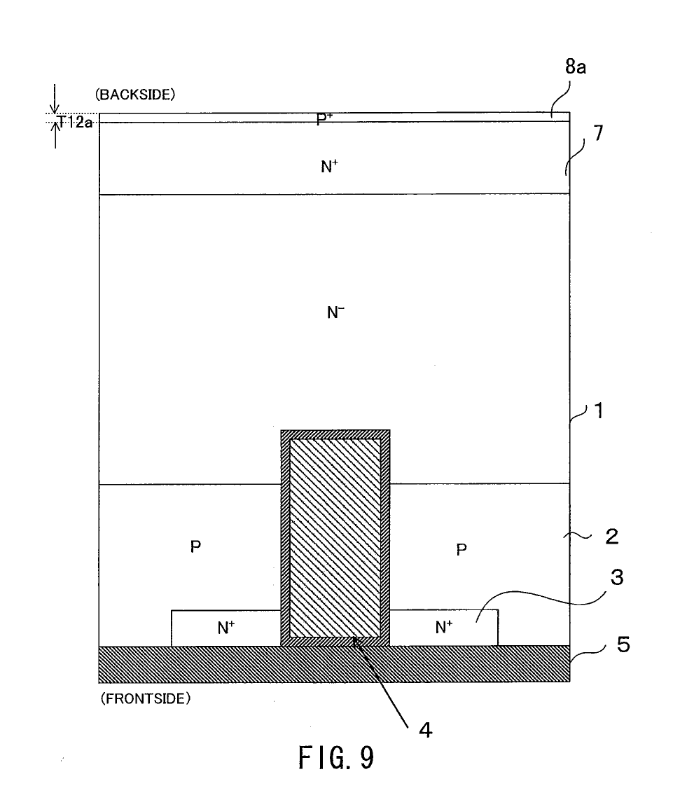

After the formation of the P⁺ amorphous silicon film 32, the P⁺ amorphous silicon film 32 is irradiated with a laser to be single-crystallized. As shown in FIG. 9, the P⁺ amorphous silicon film 32 is single-crystallized to become a first P⁺ collector layer 8a having a layer thickness T12a. Here, as the laser irradiation conditions, the same conditions as those adopted for the single crystallization of the amorphous silicon film 31 are adopted.

Thereafter, the step of irradiating with a laser the P⁺ amorphous silicon film 32 which is heavily doped with B (boron) and has the film thickness T12, and of single-crystallizing the P⁺ amorphous silicon film 32 is repeated more than once to form a P⁺ collector layer 8 having a layer thickness T2.

After the above step, a contact opening, an emitter electrode 6, a collector electrode 9 and the like are formed using well-known techniques. Thus, a punch-through type trench IGBT 90 is completed.

As described above, in the method of manufacturing a semiconductor device according to the embodiment, the first N⁺ buffer layer 7a is formed by irradiating with a laser the N⁺ amorphous silicon film 31 which is heavily doped with As (arsenic), and by thus single-crystallizing the N⁺ amorphous silicon film 31. Thereafter, the formation of the N⁺ amorphous silicon film 31 and the single-crystallization thereof using the laser are repeated more than once to form the N⁺ buffer layer 7 in the IGBT 90. Moreover, the first P⁺ collector layer 8a is formed by irradiating with a laser the N⁺ amorphous silicon film 32 which is heavily doped with B (boron), and by thus single-crystallizing the N⁺ amorphous silicon film 32. Thereafter, the formation of the P⁺ amorphous silicon film 32 and the single-crystallization thereof using the laser are repeated more than once to form the N⁺ collector layer 8 in the IGBT 90.

Thus, defects are reduced, and the IGBT 90 including the N⁺ buffer layer 7 and P⁺ collector layer 8 having a steep impurity profile can be provided.

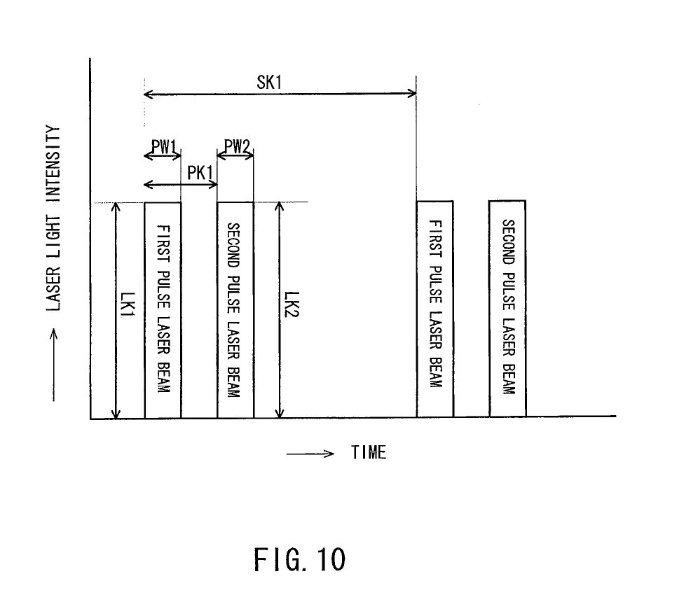

Note that, in the embodiment, the amorphous silicon film is irradiated with one kind of pulse laser and thus crystallized to form the N⁺ buffer layer and the P⁺ collector layer. However, the invention is not necessarily limited thereto. For example, the N⁺ buffer layer 7 and the P⁺ collector layer 8 may be formed using a double pulse laser as shown in FIG. 10. Here, a laser wavelength (λ) of first and second pulse laser beams is set to 532 nm. Moreover, laser light intensities LK1 and LK2 are set to 0.5 to 5 J/cm², pulse widths PW1 and PW2 are set to 100 ns, and a pulse interval PK1 is set to 700 ns. Furthermore, a shot interval SK1 is set to 0.3 to 1 msec.

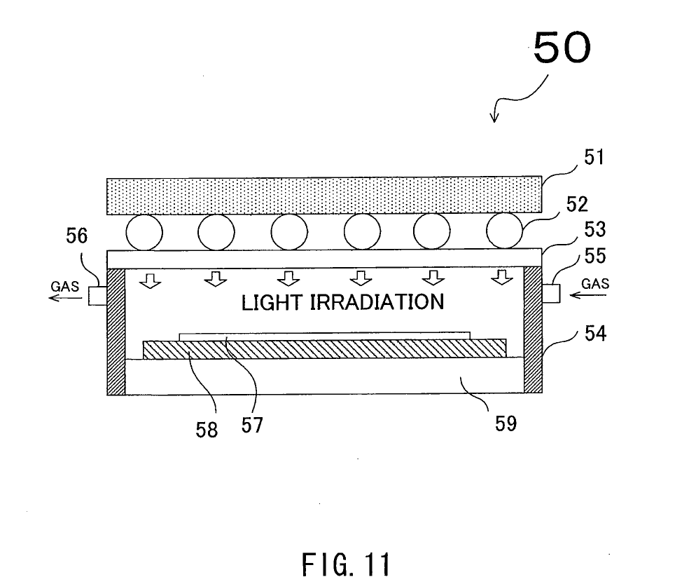

Alternatively, the N⁺ buffer layer 7 and the P⁺ collector layer 8 may be formed by a RTA (rapid thermal annealing) method using a heat treatment apparatus 50, instead of the laser irradiation, as shown in FIG. 11. Here, an amorphous silicon film is melted and single-crystallized by irradiating a wafer 57 placed on a cold plate 58 with light from a lamp 52 that is an Xe lamp or a halogen lamp in the order of msec., for example, through a quartz plate.

Although the amorphous silicon film is formed using the CVD method, the invention is not necessarily limited thereto. For example, the amorphous silicon film may be formed using a sputtering method (also referred to as a PVD method), for example, or the like.

Although the layer thickness T2 of the P⁺ collector layer 8 is set to 1 μm in the embodiment, the invention is not necessarily limited thereto. For example, the layer thickness T2 of the P⁺ collector layer 8 may be reduced to 0.3 μm. In this case, the step of forming the P⁺ amorphous silicon film 32 and single-crystallizing the P⁺ amorphous silicon film 32 by laser irradiation can be set to one cycle.

Furthermore, although the amorphous silicon film is doped with As (arsenic) to form the N⁺ amorphous silicon film, the dopant is not necessarily limited to As. For example, P (phosphorus) or the like may be used to form the N⁺ amorphous silicon film.

Furthermore, although the amorphous silicon film is doped with B (boron) to form the P⁺ amorphous silicon film, the dopant is not necessarily limited to As. For example, BF2 (boron difluoride) or the like may be used to form the P⁺ amorphous silicon film.

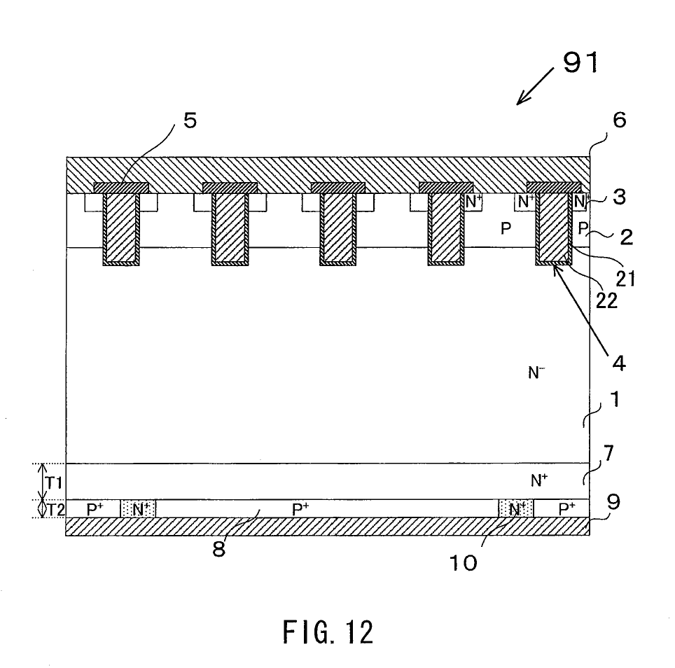

A method of manufacturing a semiconductor device according to a second embodiment is described with reference to the drawings. FIG. 12 is a cross-sectional view showing an RC-IGBT as a semiconductor device. In the embodiment, an ion-implanted amorphous silicon film is crystallized by laser irradiation to form an N⁺ buffer layer and a P⁺ collector layer.

Hereinafter, the same constituent portions as those in the first embodiment are denoted by the same reference numerals, description of the same portions is omitted, and only different portions are described.

As shown in FIG. 12, an RC-IGBT (reverse conducting-insulated gate bipolar transistor) 91 is a punch-through type trench IGBT having a gate buried in a surface of a semiconductor substrate. The RC-IGBT 91 is also referred to as a collector short IGBT, and used as a consumer or industrial power element.

In the RC-IGBT 91, a P⁺ collector layer 8 and an N⁺ collector layer 10 are provided on a second main surface (back surface) of an N⁺ buffer layer 7, the second main surface being opposite to a first main surface (front surface) of the N⁺ buffer layer 7. The P⁺ collector layer 8 has a higher impurity concentration than a P base layer 2. The N⁺ collector layer 10 has a higher impurity concentration higher than an N⁻ base layer 1. The P⁺ collector layer 8 is provided so as to surround the N⁺ collector layer 10.

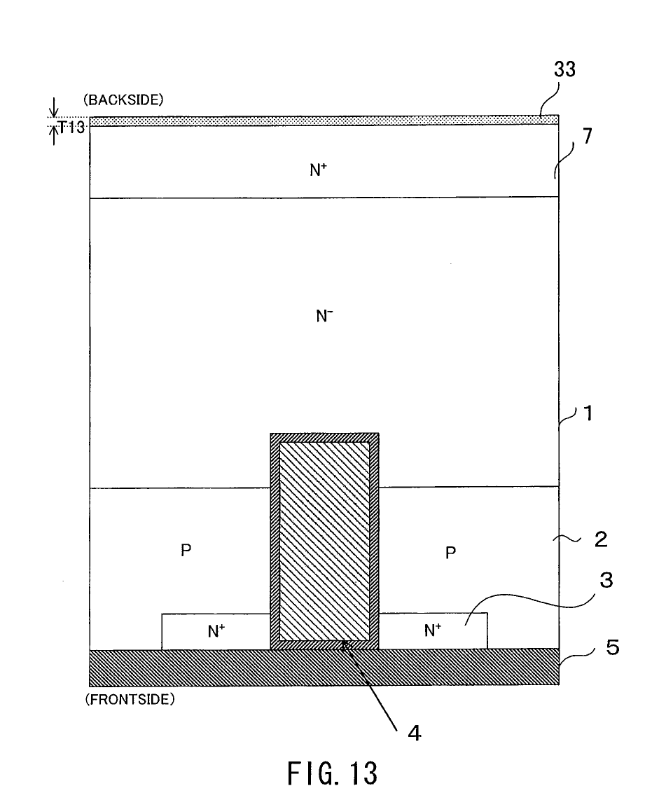

Next, a method of manufacturing an IGBT is described with reference to FIGS. 13 to 18. FIGS. 13 to 18 are cross-sectional views showing the steps of manufacturing an IGBT. Note that, in each of FIGS. 13 to 18, the upside of the drawing corresponds to the backside. The steps up to the formation of the N⁺ buffer layer 7 are the same as those in the first embodiment, and description thereof is omitted.

As shown in FIG. 13, an undoped amorphous silicon film 33 having a film thickness T13 is deposited on the second main surface (back surface) of the N⁺ buffer layer 7 by use of the CVD method, for example. For example, the CVD growth temperature is set in a range of 200 to 400° C., and the film thickness T13 is set to 0.5 μm. Here, it is preferable to select the conditions that allow the grain size of the undoped amorphous silicon film 33 to be reduced. Note that the undoped amorphous silicon film 33 may be formed using a sputtering method (also referred to as the PVD method) or the like instead of the CVD method.

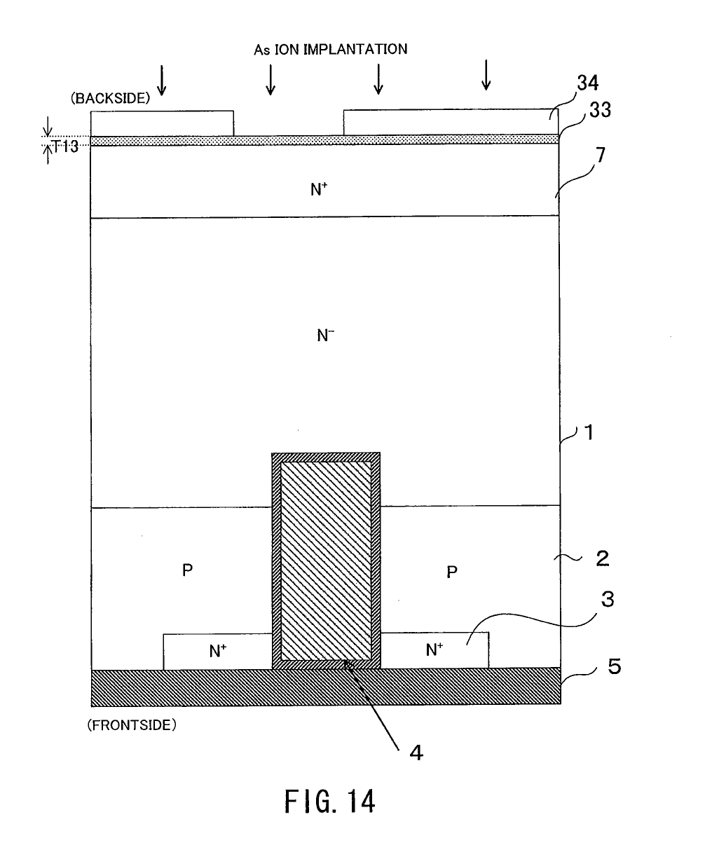

Next, as shown in FIG. 14, a resist film 34 is formed on the undoped amorphous silicon film 33 by use of a well-known lithography technique. Thereafter, As (arsenic) is ion-implanted into the undoped amorphous silicon film 33 by using the resist film 34 as a mask.

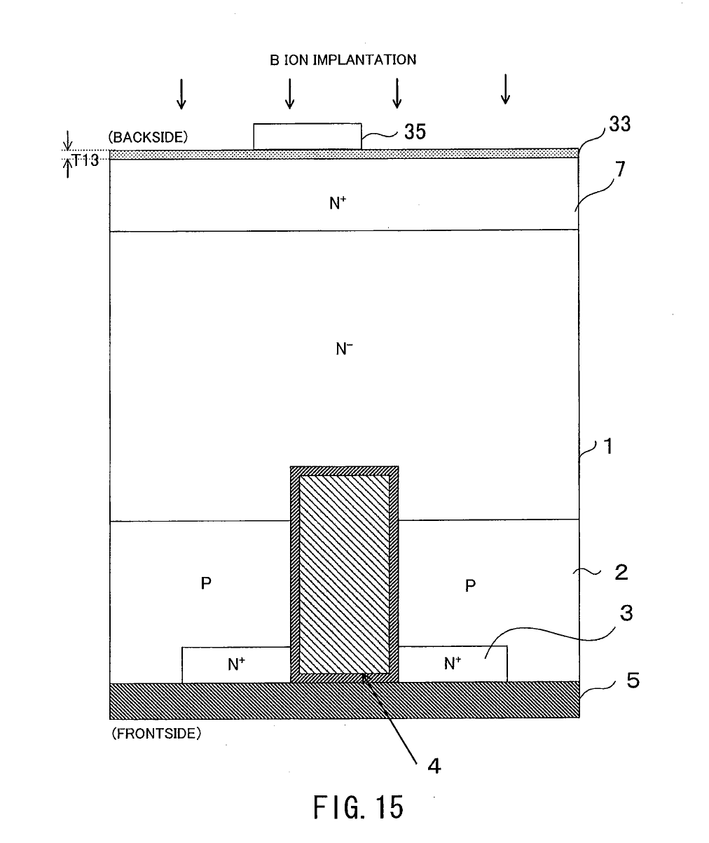

Subsequently, as shown in FIG. 15, after the resist film 34 is removed, a resist film 35 is formed on a region of the undoped amorphous silicon film 33, into which As (arsenic) is ion-implanted, by use of the well-known lithography technique. Thereafter, B (boron) is ion-implanted into the undoped amorphous silicon film 33 by using the resist film 35 as a mask.

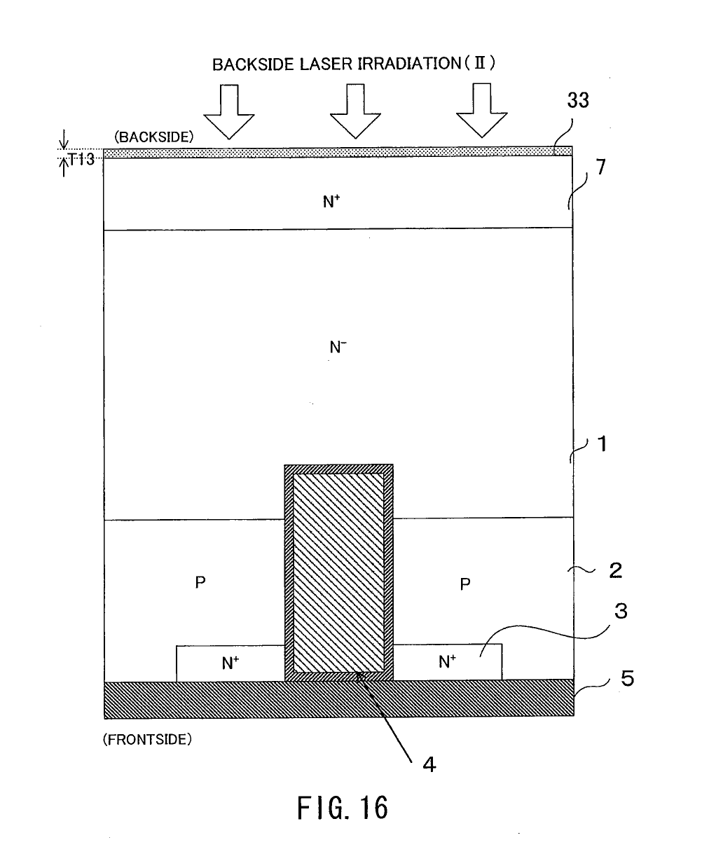

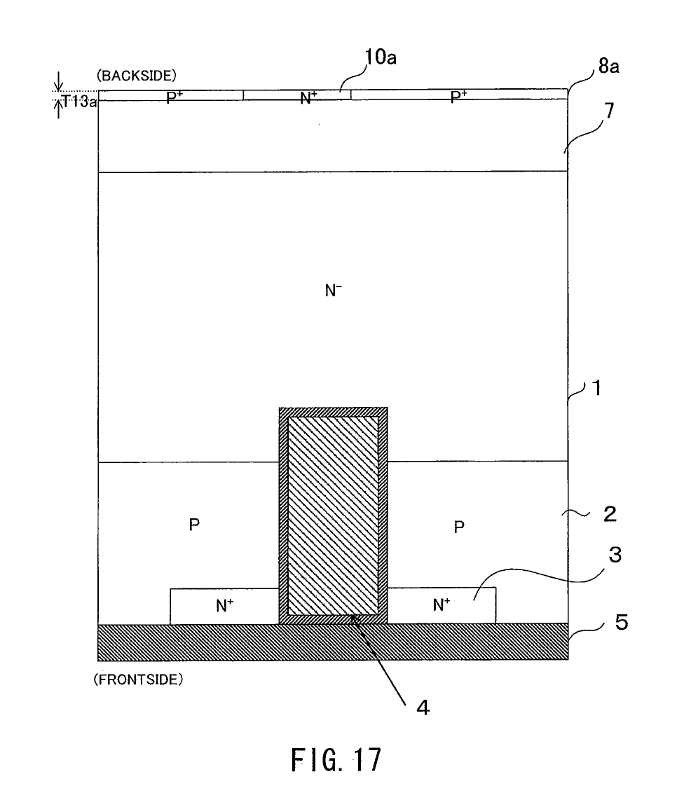

Then, as shown in FIG. 16, after the resist film 35 is removed, the ion-implanted undoped amorphous silicon film 33 is irradiated with a laser, and thus the ion-implanted undoped amorphous silicon film 33 is single-crystallized. Here, the laser irradiation is performed using the same conditions as those in the first embodiment. As shown in FIG. 17, the ion-implanted undoped amorphous silicon film 33 is single-crystallized to form a first P⁺ collector layer 8a and a first N⁺ collector layer 10a having a layer thickness T13a.

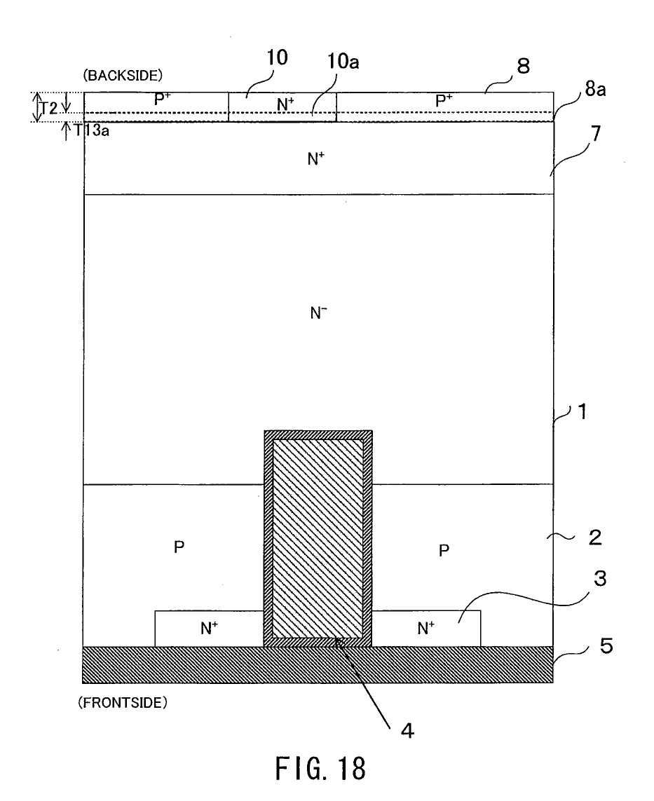

Next, as shown in FIG. 18, the step of irradiating the undoped amorphous silicon film 33, into which As (arsenic) and B (boron) are ion-implanted, with a laser and of single-crystallizing the undoped amorphous silicon film 33 is repeated more than once to form a P⁺ collector layer 8 and an N⁺ collector layer 10 having a layer thickness T2.

After the above step, a contact opening, an emitter electrode 6, a collector electrode 9 and the like are formed using well-known techniques. Thus, a punch-through type trench RC-IGBT 91 is completed.

As described above, in the method of manufacturing a semiconductor device according to the embodiment, As (arsenic) is ion-implanted into the undoped amorphous silicon film 33. Thereafter, B (boron) is ion-implanted into a region of the undoped amorphous silicon film 33, which is not ion-implanted with As (arsenic). Then, the ion-implanted undoped amorphous silicon film 33 is single-crystallized by laser irradiation to form the first N⁺ collector layer 8a and the first N⁺ collector layer 10a. The ion implantation into the undoped amorphous silicon film 33 and the single-crystallization using the laser are repeated more than once to form the P⁺ collector layer 8 and the N⁺ collector layer 10 in the RC-IGBT 91.

Thus, defects are reduced, and the RC-IGBT 91 including the N⁺ buffer layer 7, P⁺ collector layer 8 and N⁺ collector layer 10 having a steep impurity profile can be provided.

Note that, in the embodiment, the invention is applied to the punch-through type IGBT or RC-IGBT. However, the invention is not necessarily limited thereto, but may be applied to a power MOS transistor and the like.

Moreover, although the heavily-doped amorphous silicon film is single-crystallized by laser irradiation in the first embodiment, the ion-implanted amorphous silicon film may be single-crystallized by laser irradiation.

Furthermore, although As (arsenic) and B (boron) are separately ion-implanted into the undoped amorphous silicon film 33 in the second embodiment, the invention is not necessarily limited thereto. For example, As (arsenic) may be ion-implanted into the entire surface of the undoped amorphous silicon film 33, and then B (boron) may be heavily ion-implanted using a resist film only in a predetermined region as a mask.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device including a base layer of a second conductivity type provided in a front surface region of a high-resistance layer of a first conductivity type, an emitter layer of the first conductivity type provided in a front surface region of the base layer and having a higher impurity concentration than the high-resistance layer, and a gate electrode film insulated from the base layer and the emitter layer by a gate insulating film, comprising the steps of:
polishing a back surface of the high-resistance layer;
forming a first amorphous silicon film of the first conductivity type on the polished back surface of the high-resistance layer, the first amorphous silicon film having a higher impurity concentration than the high-resistance layer;
irradiating the first amorphous silicon film with a first laser and thus single-crystallizing the first amorphous silicon film; and
repeating the formation and single-crystallization of the first amorphous silicon film more than once to form a buffer layer of the first conductivity type on the back surface of the high-resistance layer, the buffer layer having a higher impurity concentration than the high-resistance layer.

2. The method of manufacturing a semiconductor device according to claim 1, further comprising the steps of:
forming a second amorphous silicon film of the second conductivity type on a back surface of the buffer layer opposite to the surface of the buffer layer in contact with the high-resistance layer, the second amorphous silicon film having a higher impurity concentration than the base layer; and
forming a collector layer of the second conductivity type on the back surface of the buffer layer by irradiating the second amorphous silicon film with a second laser and thus single-crystallizing the second amorphous silicon film, the collector layer having a higher impurity concentration than the base layer.

3. The method of manufacturing a semiconductor device according to claim 1, further comprising the steps of:
forming a second amorphous silicon film of the second conductivity type on a back surface of the buffer layer opposite to the surface of the buffer layer in contact with the high-resistance layer, the second amorphous silicon film having a higher impurity concentration than the base layer;
irradiating the second amorphous silicon film with a second laser and thus single-crystallizing the second amorphous silicon film; and
repeating the formation and single-crystallization of the second amorphous silicon film more than once to form a collector layer of the second conductivity type on the back surface of the buffer layer, the collector layer having a higher impurity concentration than the base layer.

4. The method of manufacturing a semiconductor device according to claim 1, wherein
the amorphous silicon film is formed using a CVD method or a sputtering method.

5. The method of manufacturing a semiconductor device according to claim 1, further comprising the steps of:
forming an undoped amorphous silicon film on a back surface of the buffer layer opposite to the surface of the buffer layer in contact with the high-resistance layer;
ion-implanting impurities of the first conductivity type into a first region of the undoped amorphous silicon film by using a first resist film as a mask;
ion-implanting impurities of the second conductivity type into a region of the undoped amorphous silicon film other than the first region by using a second resist film as a mask; and
single-crystallizing the ion-implanted undoped amorphous silicon film by irradiating the ion-implanted undoped amorphous silicon film with a second laser to form a first collector layer of the first conductivity type and a second collector layer of the second conductivity type on the back surface of the buffer layer, the first collector layer having a higher impurity concentration than the high-resistance layer, the second collector layer having a higher impurity concentration than the base layer.

6. The method of manufacturing a semiconductor device according to claim 1, wherein
a single pulse laser or a double pulse laser is used as the laser.

7. The method of manufacturing a semiconductor device according to claim 6, wherein
the laser is set to have a wavelength of 532 nm, and have an energy in a range of 0.5 to 5 J/cm².

8. A method of manufacturing a semiconductor device including a base layer of a second conductivity type provided in a front surface region of a high-resistance layer of a first conductivity type, an emitter layer of the first conductivity type provided in a front surface region of the base layer and having a higher impurity concentration than the high-resistance layer, and a gate electrode film insulated from the base layer and the emitter layer by a gate insulating film, comprising the steps of:
polishing a back surface of the high-resistance layer;
forming a first amorphous silicon film of the first conductivity type on the polished back surface of the high-resistance layer, the first amorphous silicon film having a higher impurity concentration than the high-resistance layer;
irradiating the first amorphous silicon film with a lamp light and thus rapidly heating and single-crystallizing the first amorphous silicon film; and
repeating the formation and single-crystallization of the first amorphous silicon film more than once to form a buffer layer of the first conductivity type on the back surface of the high-resistance layer, the buffer layer having a higher impurity concentration than the high-resistance layer.

9. The method of manufacturing a semiconductor device according to claim 8, further comprising the steps of:
forming a second amorphous silicon film of the second conductivity type on a back surface of the buffer layer opposite to the surface of the buffer layer in contact with the high-resistance layer, the second amorphous silicon film having a higher impurity concentration than the base layer; and
forming a collector layer of the second conductivity type on the back surface of the buffer layer by irradiating the second amorphous silicon film with a lamp light and thus rapidly heating and single-crystallizing the second amorphous silicon film, the collector layer having a higher impurity concentration than the base layer.

10. The method of manufacturing a semiconductor device according to claim 8, further comprising the steps of:
forming a second amorphous silicon film of the second conductivity type on a back surface of the buffer layer opposite to the surface of the buffer layer in contact with the high-resistance layer, the second amorphous silicon film having a higher impurity concentration than the base layer;
irradiating the second amorphous silicon film with a lamp light and thus rapidly heating and single-crystallizing the second amorphous silicon film; and
repeating the formation and single-crystallization of the second amorphous silicon film more than once to form a collector layer of the second conductivity type on the back surface of the buffer layer, the collector layer having a higher impurity concentration than the base layer.

11. The method of manufacturing a semiconductor device according to claim 8, wherein
the amorphous silicon film is formed using a CVD method or a sputtering method.

12. The method of manufacturing a semiconductor device according to claim 8, further comprising the steps of:
forming an undoped amorphous silicon film on a back surface of the buffer layer opposite to the surface of the buffer layer in contact with the high-resistance layer;
ion-implanting an impurity of the first conductivity type into a first region of the undoped amorphous silicon film by using a first resist film as a mask;
ion-implanting an impurity of the second conductivity type into a region of the undoped amorphous silicon film other than the first region by using a second resist film as a mask; and
single-crystallizing the ion-implanted undoped amorphous silicon film by irradiating the ion-implanted undoped amorphous silicon film with a lamp light to form a first collector layer of the first conductivity type and a second collector layer of the second conductivity type on the back surface of the buffer layer, the first collector layer having a higher impurity concentration than the high-resistance layer, the second collector layer having a higher impurity concentration than the base layer.

13. The method of manufacturing a semiconductor device according to claim 8, wherein
the lamp light is generated by an Xe lamp or a halogen lamp.
